(19) United States
(12) Patent Application Publication
(10) Pub. No.: US 2025/0175589 A1
(43) Pub. Date: May 29, 2025

(54) TEST SYSTEM FOR A CAMERA, MASK INSPECTIONS SYSTEM AND METHOD FOR TESTING A CAMERA

(71) Applicant: Carl Zeiss SMT GmbH, Oberkochen (DE)

(72) Inventors: Senthil Lakshmanan, Erfurt (DE); Lutz Brekerbohm, Hardegsen (DE); Michaela Schubert, Kraftsdorf (DE); Ulrich Matejka, Jena (DE)

(21) Appl. No.: 18/953,392

(22) Filed: Nov. 20, 2024

(30) Foreign Application Priority Data
Nov. 27, 2023 (DE) 102023133092.6

(51) Int. Cl. H04N 17/00; G03F 1/22; G03F 7/00

(52) U.S. Cl. CPC H04N 17/002; G03F 1/22; G03F 7/7085; G03F 7/70916; G03F 7/70933; G03F 7/7095

(57) ABSTRACT

A test system for a camera, comprising a camera and a first capture plate. The camera comprises a camera housing and a vacuum flange formed on the camera housing. The vacuum flange is adapted for attaching the camera to a vacuum chamber. The camera housing supports an image sensor. The image sensor comprises an image sensor surface layer. The first capture plate comprises a first capture plate surface layer. The first capture plate surface layer corresponds to the image sensor surface layer. The invention also relates to a mask inspection system and to a method for testing a camera, in particular, an EUV camera.

### CROSS-REFERENCE TO RELATED APPLICATION

The present application claims the priority of the German patent application DE 10 2023 133 092.6, filed on Nov. 27, 2023, the entire contents of which are incorporated herein by reference.

### TECHNICAL FIELD

The invention relates to a test system for a camera, a mask inspection system and a method for testing a camera. In particular, the camera may be an EUV camera.

### BACKGROUND

Photomasks are used in microlithographic projection exposure systems for the fabrication of integrated circuits with particularly small structures. The photomask is illuminated with very short-wave, extreme ultraviolet (EUV) radiation and imaged onto a lithography object to transfer the mask structure onto the lithography object.

For high quality of the image produced on the lithography object, it is necessary that the photomask is dimensionally accurate and not affected by impurities. It is known to inspect photomasks before operation in a microlithographic projection exposure system or during an interruption of operation. For this purpose, a so-called aerial image of the photomask or a section of the photomask is taken, for which the photomask is not projected onto a lithographic object, but onto an EUV image sensor of a camera. Based on the image on the EUV image sensor, an assessment can be made as to whether the photomask is free of defects and impurities.

The inspection is typically performed in a photomask inspection system with a vacuum housing, wherein a vacuum is applied in the vacuum housing during the inspection. Components of the camera, such as the image sensor, are exposed to the vacuum during the inspection.

The image sensor comprises an image sensor surface layer. The image sensor surface layer is a protective layer that is configured to protect the image sensor from the detrimental effects of EUV light.

During the inspection process, the EUV light degrades the surface of the camera, especially the image sensor surface layer. The degradation can release particles from the image sensor surface layer which can lead to contamination (e.g., with carbon) of the image sensor itself but also of other parts of the photomask inspection system such as projection mirrors.

To counteract this, the inspection system including the camera is purged with a purging gas such as hydrogen or helium. Although purging helps against EUV-induced contamination, the purging gas also erodes surface layers of components in the inspection system, e.g., the image sensor surface layer. The camera and especially the image sensor may experience outgassing effects induced by the vacuum and by the purging gas.

It is therefore foreseeable that the camera and in particular the image sensor will gradually deteriorate over time due to the exposure to EUV light and purging gas. As a result, the image sensor loses its image performance over time and will have to be exchanged after some time to maintain the inspection performance of the inspection system.

The use of cameras in EUV inspection systems for photomasks, is a recent development. Therefore, data on the long-term behavior of cameras used in inspection systems for photomasks are not yet available. However, it is desirable to be able to estimate the longevity of cameras in such systems, e.g., to estimate long-time operating cost.

### SUMMARY

It is hence an aspect of the invention to present a test system for a camera, a mask inspection system and a method for testing a camera, which can be used to estimate the longevity of cameras in inspection systems for photomasks. The object is achieved by the features of the independent claims. Advantageous embodiments are specified in the dependent claims.

According to the invention, the test system for a camera comprises a camera and a first capture plate. The camera has a camera housing and a vacuum flange formed on the camera housing. The vacuum flange is adapted for attaching the camera to a vacuum chamber. The camera housing supports an image sensor. The image sensor comprises an image sensor surface layer and the first capture plate comprises a first capture plate surface layer. The first capture plate surface layer corresponds to the image sensor surface layer.

The invention is based on the idea that during an exposure phase, higher EUV intensities can be used in the test system over a shorter period of time to predict the long-term behavior of the camera under test, which is exposed to lower EUV intensities for a longer period of time during operation in a photomask inspection system. In an evaluation phase, surfaces of parts of the test system, e.g., the first capture plate surface layer, can be analyzed.

The first capture plate can capture the EUV-induced contamination like particles and emissions that are caused by exposing the image sensor to the EUV light in the test system. Due to the first capture plate surface layer corresponding to the image sensor surface layer, an evaluation of the image sensor surface layer is possible independently from the image sensor itself. In other words, the first capture plate has the advantage that the image sensor surface layer is present once again separately from the image sensor in the test system (namely in form of the first capture plate surface layer) and during the exposure phase is exposed to the same test conditions of the test operation (e.g., EUV light intensity and a purging gas environment). With the camera and the first capture plate, the test system according to the invention hence enables a combination of both, imaging performance evaluation of the image sensor and independent surface analysis of the image sensor surface layer by analyzing the first capture plate surface layer. The combination of both allows conclusions to be drawn about the longevity of the camera.

The image sensor surface layer may comprise silicon and boron. In one embodiment, the image sensor surface layer is a layer of back side thinned silicon doped with boron implants. The first capture plate surface layer may comprise silicon and boron. In one embodiment, the first capture plate surface layer is a layer of back side thinned silicon doped with boron implants. The composition of the image sensor surface layer may be identical to the composition of the first capture plate surface layer. In a particular embodiment, the entire first capture plate is made from a material that corresponds to the material of the image sensor surface layer.

The camera may be an EUV camera. The image sensor then is an EUV image sensor, i.e., an image sensor that is sensitive to EUV light. EUV light is light in the extreme ultraviolet spectral range with wavelengths between 5 nm and 100 nm, in particular with wavelengths between 5 nm and 30 nm. Especially the EUV light can have a wavelength of 13.5 nm. The EUV camera may be adapted for use in a photomask inspection system, wherein the photomask is projected onto the EUV image sensor of the EUV camera.

The test system may comprise an evaluation unit for reading and analyzing electrical signals from the image sensor. The electrical signals from the image sensor can be used to evaluate the imaging performance of the image sensor during the evaluation phase but also during the exposure phase. For this, the EUV light intensity can be linked to the electrical signals output by the image sensor, which allows conclusions to be drawn about the state of the image sensor surface layer. The evaluation unit may comprise a memory for storing measured signals from the image sensor. The measurements can then be read from the memory for later evaluation. The evaluation may include providing a correlation between signals from the image sensor and corresponding data from the analysis data of the first capture plate surface layer.

The vacuum flange encloses an illumination area in or on the camera housing. The illumination area can be exposed to EUV light through the vacuum flange during the exposure phase. The image sensor and the first capture plate are arranged inside the illumination area. In other words, both the image sensor and the first capture plate can be exposed to EUV light through the vacuum flange during the exposure phase.

The test system may comprise a second capture plate. The second capture plate comprises a second capture plate surface layer. The second capture plate surface layer corresponds to a material surface layer used in another part of a photomask inspection system. In particular, the second capture plate surface layer may correspond to a mirror surface layer. The mirror surface layer is a material surface layer used in projection mirrors of a photomask inspection system. The second capture plate surface layer may be a ruthenium layer. It is also possible for the second capture plate surface layer to be a multilayer with alternating layers of molybdenum and silicon.

The second capture plate may be arranged inside the illumination area together with the image sensor and the first capture plate. In other words, also the second capture plate may be exposed to EUV light through the vacuum flange during the exposure phase. Like the first capture plate, the second capture plate can capture EUV-induced contamination like particles and emissions that are caused by exposing the image sensor to EUV light in the test system. When the second capture plate surface layer corresponds to the mirror surface layer, an evaluation of the long-term behavior of projection mirrors of a photomask inspection system is possible. When the second capture plate surface layer corresponds to a material layer used in another part of a photomask inspection system, an evaluation of the long-term behavior of the respective part of a photomask inspection system is possible. With the second capture plate it is hence possible to gather supplementary information about the long-term behavior of the photomask inspection system, e.g., through surface analysis of the second capture plate surface layer. In particular, if the second capture plate surface layer is a ruthenium layer, it is possible to gather supplementary information about the long-term behavior of ruthenium coated optics and mirrors used in the photomask inspection system. The second capture plate may be substrate coated with a ruthenium layer.

It is preferred that the image sensor and the first capture plate are arranged on a plane perpendicular to the axis of incidence of the EUV light incident on the illumination area. If the test system comprises a second capture plate, it is also preferred that the image sensor and the second capture plate are arranged on a plane perpendicular to the axis of incidence of the EUV light incident on the illumination area. Positioning a capture plate in the same plane as the image sensor ensures that the image sensor and capture plate are exposed to the same test conditions, such as EUV light intensity.

A capture plate may be curved or flat.

The test system may comprise a vacuum chamber, wherein the camera is attached to the vacuum chamber by use of the vacuum flange. The vacuum chamber and the camera housing together then form a vacuum housing. When a vacuum is applied to the vacuum housing, the camera housing may be under a pressure difference between the inside of the camera housing and the outside environment. The test system may comprise means for generating a vacuum in the vacuum housing, such as a vacuum pump. The image sensor and the capture plates may be exposed to the vacuum.

A structure of the test system may support the first capture plate and/or the second capture plate. In one embodiment, the camera housing supports the first capture plate and/or the second capture plate. In another embodiment, the vacuum chamber supports the first capture plate and/or the second capture plate.

During the evaluation phase, it is possible to perform the surface analysis “in-situ” while the first and the second capture plates are supported by the structure of the test system. In other embodiments, it may be desirable to remove a capture plate from the test system before performing surface analysis. For this, a capture plate, i.e., the first or the second capture plate, may be supported by the structure of the test system by use of a detachable connection for removing the capture plate from the test system. It is also possible that both the first and the second capture plates are supported by said detachable connection. The detachable connection may comprise a capture plate holder and/or EUV-resistant glue. When a capture plate is removable, the capture plate can be removed from the test system before the surface analysis of the capture plate surface layer. This is advantageous, because the capture plate surface layer can then be evaluated separately from the camera using surface analysis methods that would further damage or destroy the image sensor. For example, it is then possible to evaluate the image sensor surface layer spatially separated from the actual image sensor. The surface analysis may involve x-ray photoelectron spectroscopy (XPS) or other known methods of surface analysis.

The test system may comprise an EUV light source. The EUV light source may be arranged in the vacuum housing and have a line of sight to the illumination area. The line of sight may be straight or deflected, e.g., by directing the EUV beam originating from the EUV light source onto the illumination area via an illumination system consisting of one or more projection mirrors. The illumination system may form the EUV light to an EUV beam that illuminates the illumination area with uniform intensity. The EUV beam impinging on the image sensor may have a diameter of at least 100 mm, preferably at least 300 mm. When the test system comprises an EUV light source, the test system may comprise a control unit for controlling illumination settings of the EUV light source, e.g., EUV light intensity or illumination patterns.

The test system may comprise a first gas inlet for introducing a purging gas into the vacuum housing. The purging gas can be introduced during the exposure phase to create a purging gas environment that similarly prevails during the operation of a photomask inspection system. The camera may then be tested in a purging gas environment. The purging gas may be hydrogen or helium.

The test system may comprise a second gas inlet for introducing a dilution gas. After the exposure phase, when purging gas was introduced into the test system, the dilution gas may be introduced into the vacuum housing during a cleaning phase. The dilution gas can mix with the purging gas for diluting the purging gas to a concentration that can be safely discharged. The dilution gas may be nitrogen or another inert gas, e.g., a noble gas.

The test system may comprise a purging gas reservoir connectable to the first gas inlet. The test system may also comprise a dilution gas reservoir connectable to the second gas inlet.

The test system may comprise a first gas outlet for discharging gas out of the test system, in particular out of the vacuum housing. It is possible to feed the discharged gas, in particular a discharged gas mixture of purging gas and dilution gas into a recycling system so that the purging gas and/or the dilution gas can be reused in the test system. For this, the test system may comprise a recycling reservoir connected to the first gas outlet.

The test system may comprise a second gas outlet. The second gas outlet is useful for flushing the test system with a gas, e.g., with extreme clean dry air (XCDA). In this context, flushing means a rapid introduction and discharge of a gas, especially during the cleaning phase.

The test system may comprise a modular chamber forming a part of the vacuum housing. The modular chamber may be attached to the vacuum flange of the camera housing. The gas inlets and/or the gas outlets may be components of the modular chamber. The modular chamber then can be attached to the camera as a modular adaptor for providing the purging gas and/or diluting the purging gas with the dilution gas. When the modular chamber is attached to the camera housing, the camera housing is still attachable to a vacuum chamber via the modular chamber to form a vacuum housing. For this, the modular chamber may comprise two vacuum flanges, a first vacuum flange for attaching to the camera housing and a second vacuum flange for attaching to a vacuum chamber. Thus, the modular chamber can be arranged between the camera housing and the vacuum chamber. The vacuum chamber, the camera housing and the modular chamber then form the vacuum housing that is exposed to the vacuum and the EUV light is directed through the modular chamber to the illumination area in the camera.

The test system may comprise a pressure sensor for monitoring the pressure inside the test system, in particular inside the vacuum housing.

The test system may comprise an adaptor plate for providing illumination options. The adaptor plate is arranged between the EUV light source and the image sensor for modifying the incident EUV beam. The adaptor plate may be arranged in the camera housing or may be attached to the camera housing. It is also possible that the adaptor plate is arranged in the modular chamber or in the vacuum chamber. The adaptor plate may comprise an aperture, in particular a pinhole aperture. Only a certain portion of EUV light reaches the image sensor through a pinhole aperture, which allows to control the intensity of the incident EUV light on the illumination area. Pinhole apertures of different sizes may be provided that can be used for evaluation of the dynamic range of the image sensor. The pinhole aperture may be adjustable in size or a set of exchangeable pinhole apertures may be provided. It is also possible to provide adaptor plates for dark field imaging and white field imaging. Dark field imaging means the measurement of the dark current of the image sensor, i.e., to capture so-called dark frames. This is achieved by blocking all incident EUV light from arriving at the image sensor. White field imaging (sometimes called flat-field imaging) means illuminating the image sensor uniformly and with a high intensity, so that the dynamic range of the image sensor is measured. Dark and white field images can be used together to perform so-called flat-field correction.

It is possible that the test system comprises two modular chambers, one for the gas inlets and outlets and a second for the adaptor plate. It is also possible that the gas inlets and outlets and the adaptor plate are provided together in one modular chamber.

The image sensor may consist of a single sensor or multiple sub-sensors. The multiple sub-sensors may be arranged in a matrix or puzzle arrangement. Matrix arrangement means that the sub-sensors are arranged in a rectangle or square shape in rows and columns next to each other. Puzzle arrangement means that neighboring sub-sensors are arranged horizontally or vertically offset from each other, so that steps are formed within the arrangement.

Especially when the sub-sensors are arranged in a puzzle arrangement, although not limited to this arrangement, not all portions of the image sensor may be fully used for mask inspection in a photomask inspection system due to the formed steps and symmetry constraints. In other words, not all portions of the image sensor are then fully used for the imaging performance of the image sensor. Therefore, in one embodiment of the invention, unused portions of the image sensor-that are not used for mask inspection in a photomask inspection system-may be used for energy monitoring of the incident light, in particular EUV light. In other words, the image sensor may comprise energy monitoring portions for monitoring the energy of the incident light.

A calibrated photodiode may be arranged within the illumination area inside the camera housing. It is preferred that the image sensor and the photodiode are arranged on a plane perpendicular to the axis of incidence of the EUV light incident on the illumination area. Signals from the calibrated photodiode can be used for calibrating signals from the image sensor and for energy monitoring of the incident light.

The invention also relates to a mask inspection system, comprising a camera, a positioning device for a photomask and a projection lens for imaging the photomask onto an image sensor of the camera, the camera having a camera housing and a vacuum flange formed on the camera housing, wherein the vacuum flange is attached to a vacuum chamber of the mask inspection system, wherein the camera housing supports an image sensor, the image sensor having an image sensor surface layer, the mask inspection system further comprising a first capture plate, the first capture plate having a first capture plate surface layer, wherein the first capture plate is adapted for capturing EUV-induced contamination like particles and emissions that are caused by exposing the image sensor to the EUV light in the test system, and wherein the first capture plate surface layer corresponds to the image sensor surface layer, so that the composition of the image sensor surface layer is identical to the composition of the first capture plate surface layer.

The invention also relates to a method for testing a camera, in which the camera comprises a camera housing and a vacuum flange formed on the camera housing. The vacuum flange is adapted for attaching the camera to a vacuum chamber. The camera housing supports an image sensor. The image sensor comprises an image sensor surface layer and a first capture plate comprises a first capture plate surface layer. The first capture plate surface layer corresponds to the image sensor surface layer. The method comprises a preparation phase in which the image sensor surface layer and the first capture plate surface layer are exposed to a vacuum, an exposure phase in which the image sensor surface layer and the first capture plate surface layer are exposed to EUV light, and an evaluation phase in which the first capture plate surface layer is examined.

The vacuum may be created within a vacuum housing such that the image sensor and the first capture plate are exposed to the vacuum. For this, the camera housing may be attached to a vacuum chamber by use of the vacuum flange to form the vacuum housing.

A purging gas may be introduced into the test system such that the image sensor and the first capture plate are exposed to the purging gas.

Creating the vacuum and introducing the purging gas may be performed before the exposure phase in a preparation phase.

During a cleaning phase, the purging gas may be mixed with a diluting gas. The gas mixture then may be discharged out of the test system.

During the evaluation phase, before the surface layer of the first capture plate is examined, the first capture plate may be removed from the camera.

When the test system comprises a second capture plate, method steps that are applicable to the first capture plate may also be applied to the second capture plate.

The exposure phase may last for at least a day, preferably at least a month, more preferably at least a year.

The disclosure encompasses developments of the method with features that are described in the context of the test system according to the invention. The disclosure encompasses developments of the test system that are described in the context of the method according to the invention.

### BRIEF DESCRIPTION OF DRAWINGS

The invention is described by way of example hereinafter using advantageous embodiments, with reference to the appended drawings. The figures show:

FIG. 1: a schematic illustration of a photomask inspection system;

FIG. 2: a schematic illustration of a photomask;

FIG. 3: a top view of an embodiment of a test system;

FIG. 4: a side view of the test system of FIG. 3;

FIG. 5: an inventive test system comprising a vacuum chamber;

FIG. 6: an inventive test system comprising a modular chamber;

FIG. 7: an image sensor of an inventive test system;

FIG. 8-9: alternative embodiments of an image sensor;

FIG. 10: an example of use of the image sensor of FIG. 9;

FIG. 11: an alternative embodiment of a test system according to the invention.

### DETAILED DESCRIPTION

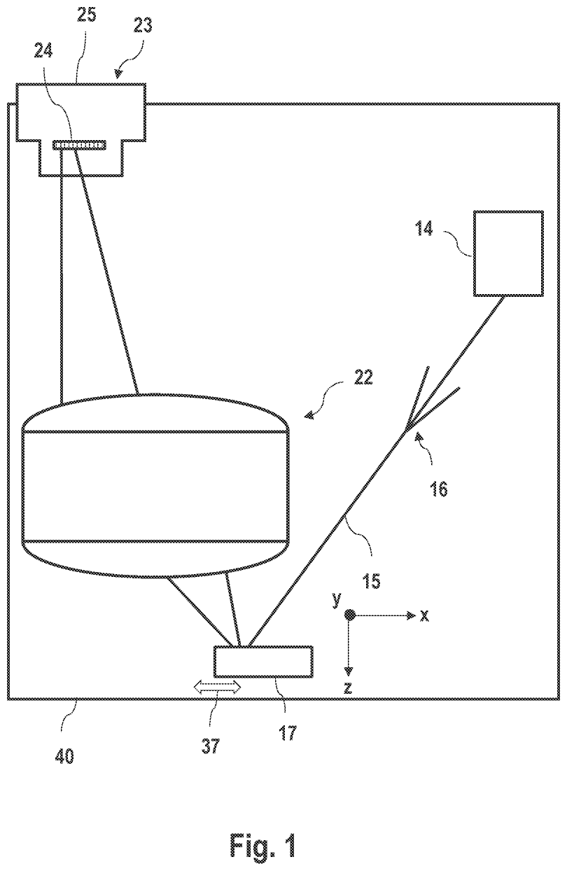

A photomask inspection system as shown in FIG. 1 can be used to inspect microlithographic photomasks 17.

Microlithographic photomasks 17 are generally intended to be used in a microlithographic projection illumination system (not shown). In the microlithographic projection illumination system, the photomask 17 is illuminated with extreme ultraviolet (EUV) radiation having a wavelength of, for example, 13.5 nm to image a pattern formed on the photomask 17 onto the surface of a lithography object in the form of a wafer. The wafer is coated with a photoresist that reacts to the EUV radiation. The photomask inspection system is used to examine whether the photomask complies with the specifications and is free of impurities.

The photomask 17 may have an aspect ratio of between 1:1 and 1:3, preferably between 1:1 and 1:2, more preferably of 1:1 or 1:2. The photomask 17 may have a substantially rectangular shape. The photomask 17 may preferably be 5 to 7 inches (12.7 to 17.78 cm) long and wide, more preferably 6 inches (15.24 cm) long and wide. Alternatively, the photomask 17 may be 5 to 7 inches (12.7 to 17.78 cm) long and 10 to 14 inches (25.4 to 35.56 cm) wide, preferably 6 inches (15.24 cm) long and 12 inches (30.48 cm) wide.

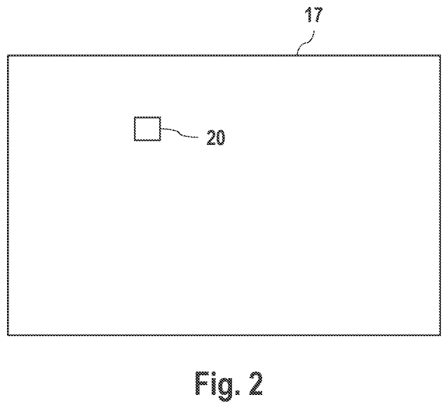

In the photomask inspection system, according to FIG. 1, the photomask 17 is arranged in such a way that an EUV beam 15 emitted from an EUV light source 14 is directed to the photomask 17 via an illumination system 16. The illumination system 16 is used to form the EUV radiation into a beam that is used to illuminate an examination field 20 on the surface of the photomask 17 with uniform intensity. The examination field 20, which is small in relation to the surface of the photomask 17, is shown in a non-scale representation in FIG. 2. For example, the illuminated area 20 may have dimensions of 0.5 mm×0.8 mm. A field diaphragm is arranged in the illumination system 16 to limit the illuminated area to the examination field 20 on the surface of the photomask 17. An X-Y positioner 37 can be used to move the photomask in the X-Y plane to bring various examination fields 20 within the range of the EUV beam path.

The EUV beam 15 reflected from the photomask 17 continues through a projection optics 22 to an EUV camera 23 equipped with an image sensor 24. For example, the image sensor 24 can have an array of EUV light sensing elements. The projection optics images the examination field 20 of the photomask 17 onto the image sensor 24 of the EUV camera 23. The EUV light source 14, the illumination system 16, the photomask 17, the projection optics 22, and the EUV camera 23 are arranged in a vacuum housing 40 in which a negative pressure is applied during operation of the inspection system. The EUV camera 23 includes a camera housing 25 within which the image sensor 24 is arranged. A rear portion of the camera housing 25 protrudes from the vacuum housing 40 while the image sensor 24 is exposed to the vacuum in the vacuum housing 40. Accordingly, the camera housing 25 forms a portion of the vacuum housing 40 and is exposed to the same pressure differential as other portions of the vacuum housing.

In some examples, the EUV light source 14 is a plasma light source in which an EUV beam with a wavelength of 13.5 nm is emitted from a plasma. Tin or Xenon are media that can be used to generate a plasma suitable for emitting such EUV beam. To generate the plasma, a droplet of the medium can be exposed to a laser beam.

The mirrors of the illumination system 16 as well as the mirrors of the projection optics 22 are designed as EUV mirrors, which have a particularly high reflectivity for EUV beams. The optical surface of the EUV mirrors may be formed by a highly reflective coating. It can be a multilayer coating, in particular a multilayer coating with alternating layers of molybdenum and silicon. With such a coating, about 70% of the incident EUV beam can be reflected. In case of a so-called grazing incidence mirror, the optical surface may be formed by a ruthenium layer.

The projection optics 22 has a magnification factor greater than 100. In order to fully capture the image produced by the examination field 20 of the photomask 17, the area of the image sensor 24 is greater than the area of the examination field 20 in accordance with the magnification factor. For example, the image sensor 24 may have dimensions on the order of 100 mm to 200 mm.

During the inspection process, the EUV light 15 degrades the surface of the image sensor 24, such that particles from the image sensor surface layer contaminate the image sensor 24 itself but also of other parts of the photomask inspection system 16, 22. To counteract this, the vacuum housing 40 is purged with hydrogen as a purging gas. Although the purging gas helps against the EUV-induced contamination, the purging gas also erodes surface layers of components in the inspection system, e.g., the image sensor 24. The image sensor 24 experiences outgassing effects induced by the vacuum in the vacuum housing 40 and by the purging gas.

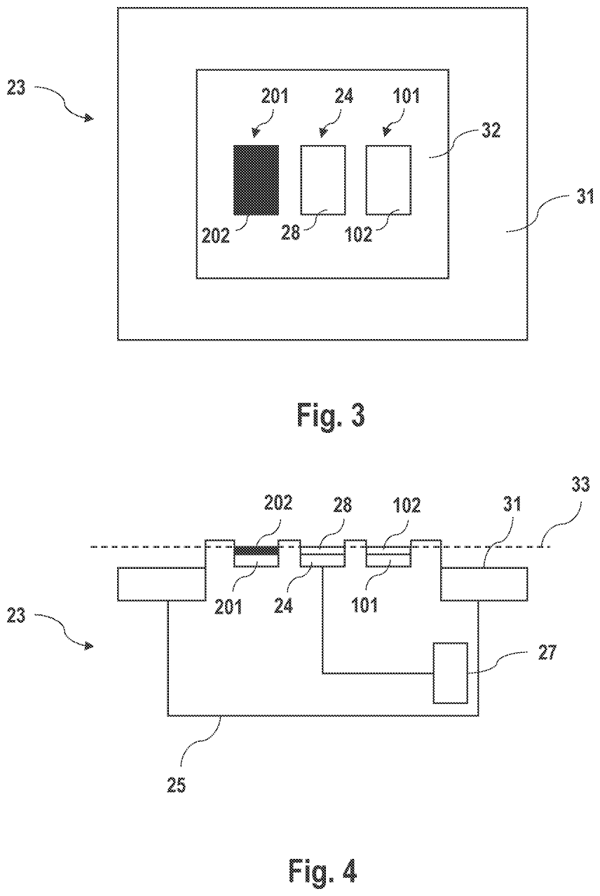

FIGS. 3 and 4 illustrate a test system according to the invention for testing an EUV camera 23. The test system comprises an EUV camera 23, a flat first capture plate 101 and a flat second capture plate 201. The EUV camera 23 has a camera housing 25 and a vacuum flange 31 formed on the camera housing 25. The vacuum flange 31 is adapted for attaching the EUV camera 23 to a vacuum chamber 41. The camera housing 25 supports an image sensor 24, the first capture plate 101 and the second capture plate 201. Since the camera 23 is an EUV camera, the image sensor 24 is sensitive to EUV light.

The image sensor 24 comprises an image sensor surface layer 28, the first capture plate comprises a first capture plate surface layer 102 and the second capture plate comprises a second capture plate surface layer 202. The first capture plate surface layer 102 corresponds to the image sensor surface layer 28. The image sensor surface layer 28 and the first capture plate surface layer 102 are both back side thinned silicon doped with boron implants. The second capture plate surface layer 202 is a ruthenium layer that is applied to a substrate and as such corresponds to a mirror surface layer, i.e., a material surface layer used in the projection mirrors of the projection optics 22 in the inspection system according to FIG. 1.

During an exposure phase, higher EUV intensities are used in the test system than in the inspection system (FIG. 1) for a shorter period of time in order to predict the long-term behavior of the camera. Even though the exposure phase is shorter than the lifetime of a camera in an inspection system, it can still last a year or more.

In the embodiment shown in FIGS. 3 and 4, the first capture plate 101 and the second capture plate 201 capture EUV-induced contamination like particles and emissions that are caused by exposing the image sensor 24 to EUV light. Because the first capture plate surface layer 102 corresponds to the image sensor surface layer 28, the image sensor surface layer 28 is present twice in the test system. Therefore, due to the first capture plate 101, the image sensor surface layer 28 can be evaluated independently from the image sensor 24 itself.

The test system comprises an evaluation unit 27 for reading and analyzing electrical signals from the image sensor 24. For this, the evaluation unit 27 is electrically connected to the image sensor 24.

The vacuum flange 31 encloses an illumination area 32 on the camera housing 25. During the exposure phase, the illumination area 32 is exposed to EUV light. The image sensor 24 and both the first and second capture plate 101, 201 are arranged inside the illumination area 32 and hence exposed to EUV light during the exposure phase.

The image sensor 24 and both the first and second capture plates 101, 201 are arranged on a plane 33 perpendicular to the axis of incidence of the EUV light incident on the illumination area 32. Therefore, the image sensor surface layer 28 as well as both the first and second capture plate surface layers 102, 202 are exposed to the same EUV light intensity.

The first and second capture plates 101, 201 are supported by the camera housing by use of a detachable connection. In the shown embodiment, the detachable connection is an EUV-resistant glue.

During the evaluation phase, no EUV light is active, and the illumination area is hence not exposed to EUV light. The first and second capture plates 101, 201 are removed from the camera housing 25 by loosening the glued connection. Subsequently, the first and second capture plate surface layers 102, 202 are analyzed separately from the camera 23 using XPS, i.e., a surface analysis method.

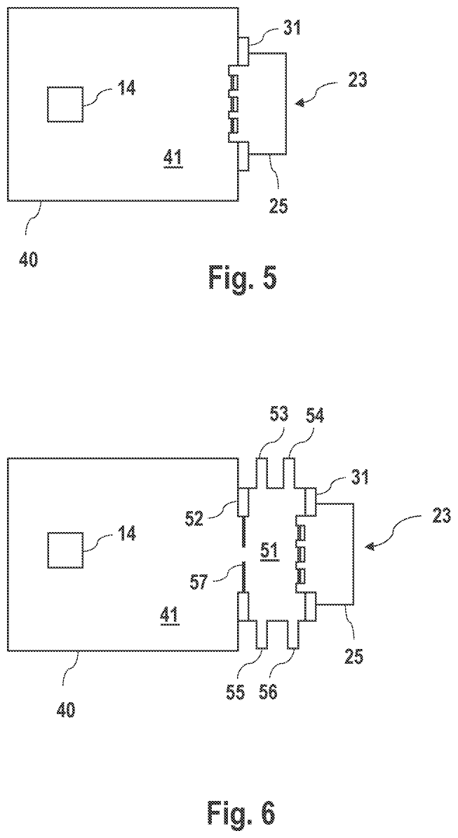

As shown in FIG. 5, according to one embodiment, the test system comprises a vacuum chamber 41, wherein the camera 23 is attached to the vacuum chamber 41 by use of the vacuum flange 31. The vacuum chamber 41 and the camera housing 25 together form a vacuum housing 40. The vacuum chamber comprises means for generating a vacuum in the vacuum housing 40. The image sensor 24 as well as both capture plates 101, 201 are exposed to the vacuum inside the vacuum housing 40, i.e., there is a pressure difference over the camera housing 25 to the outside environment. An EUV light source 14 is arranged inside the vacuum housing 40. The EUV light source 14 has a line of sight to the illumination area 32 that is deflected by multiple projection mirrors (not shown) that are also arranged inside the vacuum chamber 41. The EUV light that arrives at the illumination area illuminates the illumination area 32 in a uniform manner.

FIG. 6 shows another embodiment of the test system. A modular chamber 51 is arranged between the camera 23 and the vacuum chamber 41. The modular chamber 51 is attached to the vacuum chamber 41 by use of a vacuum flange 52, while the camera housing 25 is attached to the modular chamber 51 by use of its vacuum flange 31. The vacuum chamber 41, the modular chamber 51 and the camera housing 25 form a vacuum housing 40, i.e., there is a pressure difference over the modular chamber 51 and the camera housing 25 to the outside environment. The EUV light originating from the EUV light source 14 is directed through the modular chamber 51 to the camera 23.

A first gas inlet 53 is arranged in the modular chamber 51. During the exposure phase, hydrogen is introduced as a purging gas into the vacuum housing 40 via the modular chamber 51 to create a purging gas environment. The camera 23 is exposed to a purging gas environment that is similar to the purging gas environment in the inspection system according to FIG. 1.

A second gas inlet 54 is arranged in the modular chamber 51 for introducing nitrogen as a dilution gas into the vacuum housing 40 during a cleaning phase. The nitrogen dilutes the hydrogen inside the vacuum housing 40 to a concentration that can be safely discharged.

For discharging gas out of the vacuum housing 40, first and second gas outlets 55, 56 are arranged in the modular chamber 51. In one step during the cleaning phase, the vacuum housing 40 is flushed with XCDA by rapidly introducing and discharging the gas via all gas inlets and outlets.

An adaptor plate 57 is arranged between the modular chamber 51 and the vacuum chamber 41, i.e., between the EUV light source 14 and the image sensor 24 on the camera housing 25. The adaptor plate 57 comprises a pinhole aperture, i.e., only a certain portion of EUV light reaches the image sensor 24 through the adaptor plate 57.

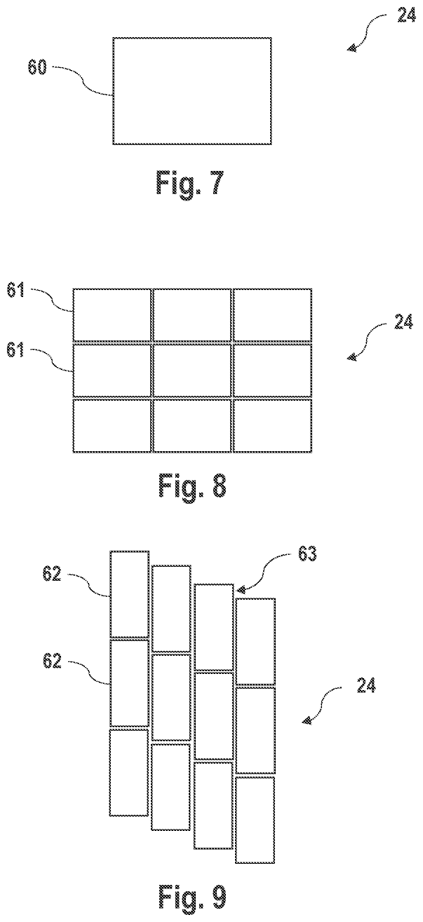

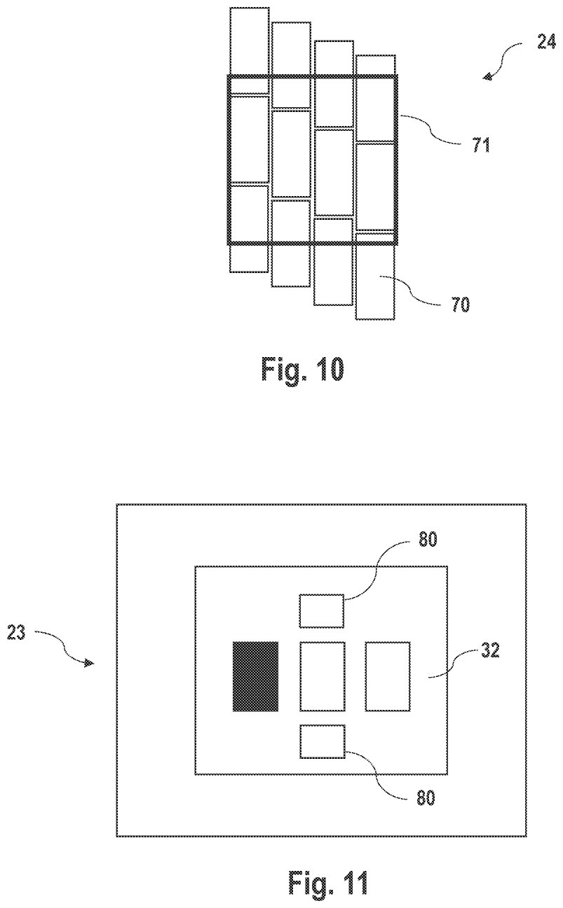

According to the embodiment shown in FIG. 7, the image sensor 24 consists of a single sensor 60. FIG. 8 shows an embodiment in which the image sensor 24 consists of multiple sub-sensors 61 arranged in a matrix arrangement. FIG. 9 shows an embodiment in which the image sensor 24 consists of multiple sub-sensors 62 arranged in a puzzle arrangement. The sub-sensors 62 are arranged such that neighboring sub-sensors 62 are arranged vertically offset from each other, so that steps 63 are formed within the arrangement. For example, each sub-sensor 61 or 62 can include a plurality of (e.g., an array of) pixels or sensing elements. FIG. 10 shows the puzzle arrangement according to FIG. 9 and indicated the active area 71 of the image sensor 24 actually used for imaging performance. The portions 70 outside the active area 71 do not contribute to the imaging performance but are used for monitoring the energy of the incident EUV light. The portions 70 are called energy monitoring portions.

FIG. 11 shows another embodiment of the test system in which photodiodes 80 are arranged in the illumination area 32 in the vicinity of the image sensor 24. The photodiodes 80 are arranged on the plane 33 (FIG. 4) such that they are exposed to the same EUV light intensity as the image sensor 24 and the capture plates 101, 201. The photodiodes 80 are calibrated before they are placed in the camera 23. Therefore, signals from the calibrated photodiodes 80 are used for calibrating signals form the image sensor 24 and for monitoring the incident EUV light intensity.

In some implementations, the evaluation unit can include one or more digital signal processors, or one or more computing devices configured to analyze data from the image sensor. For example, one or more computing devices can be configured to receive data derived from the surface analysis of the capture plate surface layers, analyze the data, determine the amount of damage of the capture plate surface layers, and predict the long-term behavior of the camera, optics and mirrors used in the photomask inspection system.

The one or more computing devices can include one or more data processors for processing data, one or more storage devices for storing data, and/or one or more computer programs including instructions that when executed by the one or more computing devices cause the one or more computing devices to carry out the method steps or processing steps. The camera or the one or more computing devices can include one or more input devices, such as a keypad, a keyboard, a joystick, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computing devices can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks.

Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Although the present invention is defined in the attached claims, it should be understood that the present invention can also be defined in accordance with the following embodiments:

Embodiment 1. A test system for a camera, comprising the camera (23) and a first capture plate (101), the camera (23) having a camera housing (25) and a vacuum flange (31) formed on the camera housing (25), wherein the vacuum flange (31) is adapted for attaching the camera (23) to a vacuum chamber (41), wherein the camera housing (25) supports an image sensor (24), wherein the image sensor (24) comprises an image sensor surface layer (28), wherein the first capture plate (101) comprises a first capture plate surface layer (102), and wherein the first capture plate surface layer (102) corresponds to the image sensor surface layer (28).

Embodiment 2. The test system according to embodiment 1, wherein the camera housing (25) supports the first capture plate (101).

Embodiment 3. The test system according to embodiment 1 or 2, comprising a second capture plate (201), wherein the second capture plate (201) comprises a second capture plate surface layer (202).

Embodiment 4. The test system according to embodiment 3, wherein the second capture plate surface layer (202) is a ruthenium layer.

Embodiment 5. The test system according to embodiment 3 or 4, wherein the camera housing (25) supports the second capture plate (201).

Embodiment 6. The test system according to any of embodiments 1 to 5, comprising an evaluation unit (27) for reading a signal from the image sensor (24).

Embodiment 7. The test system according to any of embodiments 1 to 6, comprising a vacuum chamber (41), wherein the camera housing (25) and the vacuum chamber (41) form parts of a vacuum housing (40), and wherein a pressure difference is provided between the inside of the vacuum housing (40) and an external environment.

Embodiment 8. The test system according to embodiment 7, comprising an EUV light source (14) that is arranged inside the vacuum housing (40) and has a line of sight to an illumination area (32) for exposing the image sensor (24) and the first capture plate (101) to EUV light.

Embodiment 9. The test system according to any of embodiments 1 to 8, comprising a first gas inlet (53) for introducing a purging gas and exposing the image sensor (24) and the first capture plate (101) to the purging gas, and a first gas outlet (55) for discharging gas.

Embodiment 10. The test system according to embodiment 9, wherein the purging gas is hydrogen and/or helium.

Embodiment 11. The test system according to embodiment 9 or 10, with a second gas inlet (54) for introducing a diluting gas, wherein the diluting gas is nitrogen or an inert gas.

Embodiment 12. The test system according to any of embodiments 7 to 11, comprising a modular chamber (51) that is arranged between the vacuum chamber (41) and the camera housing (25) and forms a part of the vacuum housing (40).

Embodiment 13. The test system according to embodiment 12, wherein the first gas inlet (53) and the second gas inlet (54) are arranged in the modular chamber (51).

Embodiment 14. The test system according to any of embodiments 8 to 13, comprising an adaptor plate (57) for providing illumination options, wherein the adaptor plate (57) comprises a pinhole aperture or is adapted for dark field imaging or is adapted for white field imaging.

Embodiment 15. The test system according to any of embodiments 1 to 14, wherein the image sensor (24) consists of a single sensor (60) or multiple sub-sensors in a matrix arrangement (61) or multiple sub-sensors in a puzzle arrangement (62).

Embodiment 16. The test system according to any of the embodiments 6 to 15, comprising a calibrated photodiode (80) for calibrating the signal from the image sensor (24).

Embodiment 17. The test system according to any of the embodiments 1 to 16, wherein the camera (23) is an EUV camera.

Embodiment 18. The test system according to any of embodiments 1 to 17, wherein the first capture plate surface layer (102) corresponds to the image sensor surface layer (28), so that the composition of the image sensor surface layer (28) is identical to the composition of the first capture plate surface layer (102).

Embodiment 19. A mask inspection system, comprising a camera (23), a positioning device (26) for a photomask and a projection lens (22) for imaging the photomask (17) onto an image sensor (24) of the camera (23), the camera (23) having a camera housing (25) and a vacuum flange (31) formed on the camera housing (25), wherein the vacuum flange (31) is attached to a vacuum chamber (41) of the mask inspection system, wherein the camera housing (25) supports an image sensor (24), the image sensor (24) having an image sensor surface layer (28), the mask inspection system further comprising a first capture plate (101), the first capture plate (101) having a first capture plate surface layer (102), wherein the first capture plate (101) is adapted for capturing EUV-induced contamination like particles and emissions that are caused by exposing the image sensor (24) to the EUV light in the test system, and wherein the first capture plate surface layer (102) corresponds to the image sensor surface layer (28), so that the composition of the image sensor surface layer (28) is identical to the composition of the first capture plate surface layer (102).

Embodiment 20. A method for testing a camera, in which the camera (23) comprises a camera housing (25) and a vacuum flange (31) formed on the camera housing, wherein the vacuum flange (31) is adapted for attaching the camera (23) to a vacuum chamber (41), wherein the camera housing (25) supports an image sensor (24), wherein the image sensor (24) comprises an image sensor surface layer (28), wherein a first capture plate (101) comprises a first capture plate surface layer (102), wherein the first capture plate surface layer (102) corresponds to the image sensor surface layer (28), with a preparation phase in which the image sensor surface layer (28) and the first capture plate surface layer (102) are exposed to a vacuum, an exposure phase in which the image sensor surface layer (28) and the first capture plate surface layer (102) are exposed to EUV light, and an evaluation phase in which the first capture plate surface layer (102) is examined.

A number of embodiments of the invention have been described. Nevertheless, it will be understood that various modifications may be made without departing from the spirit and scope of the invention. In the example shown in FIG. 4, three or more capture plates can be arranged next to or near the image sensor. Accordingly, other embodiments are within the scope of the following claims.

What is claimed is:

1. A test system for a camera, comprising the camera and a first capture plate, the camera having a camera housing and a vacuum flange formed on the camera housing, wherein the vacuum flange is adapted for attaching the camera to a vacuum chamber, wherein the camera housing supports an image sensor, wherein the image sensor comprises an image sensor surface layer, wherein the first capture plate comprises a first capture plate surface layer, and wherein the first capture plate surface layer corresponds to the image sensor surface layer.

2. The test system of claim 1, wherein the camera housing supports the first capture plate.

3. The test system of claim 1, comprising a second capture plate, wherein the second capture plate comprises a second capture plate surface layer.

4. The test system of claim 3, wherein the second capture plate surface layer is a ruthenium layer.

5. The test system of claim 3, wherein the camera housing supports the second capture plate.

6. The test system of claim 1, comprising an evaluation unit for reading a signal from the image sensor.

7. The test system of claim 1, comprising a vacuum chamber, wherein the camera housing and the vacuum chamber form parts of a vacuum housing, and wherein a pressure difference is provided between the inside of the vacuum housing and an external environment.

8. The test system of claim 7, comprising an EUV light source that is arranged inside the vacuum housing and has a line of sight to an illumination area for exposing the image sensor and the first capture plate to EUV light.

9. The test system of claim 1, comprising a first gas inlet for introducing a purging gas and exposing the image sensor and the first capture plate to the purging gas, and a first gas outlet for discharging gas.

10. The test system of claim 9, wherein the purging gas is hydrogen and/or helium.

11. The test system of claim 9, with a second gas inlet for introducing a diluting gas, wherein the diluting gas is nitrogen or an inert gas.

12. The test system of claim 7, comprising a modular chamber that is arranged between the vacuum chamber and the camera housing and forms a part of the vacuum housing.

13. The test system of claim 12, wherein the first gas inlet and the second gas inlet are arranged in the modular chamber.

14. The test system of claim 8, comprising an adaptor plate for providing illumination options, wherein the adaptor plate comprises a pinhole aperture or is adapted for dark field imaging or is adapted for white field imaging.

15. The test system of claim 1, wherein the image sensor consists of a single sensor or multiple sub-sensors in a matrix arrangement or multiple sub-sensors in a puzzle arrangement.

16. The test system of claim 6, comprising a calibrated photodiode for calibrating the signal from the image sensor.

17. The test system of claim 1, wherein the camera is an EUV camera.

18. The test system of claim 1, wherein the first capture plate surface layer corresponds to the image sensor surface layer, so that the composition of the image sensor surface layer is identical to the composition of the first capture plate surface layer.

19. A mask inspection system, comprising a camera, a positioning device for a photomask and a projection lens for imaging the photomask onto an image sensor of the camera, the camera having a camera housing and a vacuum flange formed on the camera housing, wherein the vacuum flange is attached to a vacuum chamber of the mask inspection system, wherein the camera housing supports an image sensor, the image sensor having an image sensor surface layer, the mask inspection system further comprising a first capture plate, the first capture plate having a first capture plate surface layer, wherein the first capture plate is adapted for capturing EUV-induced contamination like particles and emissions that are caused by exposing the image sensor to the EUV light in the test system, and wherein the first capture plate surface layer corresponds to the image sensor surface layer, so that the composition of the image sensor surface layer is identical to the composition of the first capture plate surface layer.

20. A method for testing a camera, in which the camera comprises a camera housing and a vacuum flange formed on the camera housing, wherein the vacuum flange is adapted for attaching the camera to a vacuum chamber, wherein the camera housing supports an image sensor, wherein the image sensor comprises an image sensor surface layer, wherein a first capture plate comprises a first capture plate surface layer, wherein the first capture plate surface layer corresponds to the image sensor surface layer, with a preparation phase in which the image sensor surface layer and the first capture plate surface layer are exposed to a vacuum, an exposure phase in which the image sensor surface layer and the first capture plate surface layer are exposed to EUV light, and an evaluation phase in which the first capture plate surface layer is examined.
